(19) United States
(12) Patent Application Publication
(10) Pub. No.: US 2024/0329322 A1
(43) Pub. Date: Oct. 3, 2024

(54) LOW REFRACTIVE INDEX MATERIALS ON THE GRATINGS TO IMPROVE THE WAVEGUIDE EFFICIENCY

(71) Applicant: Applied Materials, Inc., Santa Clara, CA (US)

(72) Inventors: Jinyu LU, Santa Clara, CA (US); Ludovic Godet, Sunnyvale, CA (US); Jinxin FU, Fremont, CA (US); Kenichi OHNO, Sunnyvale, CA (US); Shangyi Chen, Santa Clara, CA (US); Takashi KURATOMI, San Jose, CA (US); Erica CHEN, Cupertino, CA (US); Rami HURARNI, Santa Clara, CA (US); Yangyang SUN, San Jose, CA (US)

(21) Appl. No.: 18/625,979

(22) Filed: Apr. 3, 2024

Related U.S. Application Data
(60) Provisional application No. 63/456,662, filed on Apr. 3, 2023.

(51) Int. Cl. G02B 6/34; C23C 16/40; C23C 16/455

(52) U.S. Cl. CPC G02B 6/34; C23C 16/403; C23C 16/45553

(57) ABSTRACT

Embodiments described herein relate to improved waveguides with materials layers improving the optical properties of one or more surface regions of waveguides and methods of forming the same. In one embodiment, a waveguide is provided. The waveguide including a substrate, a grating disposed in or on the substrate, the grating comprising a plurality of structures defined by a plurality of trenches, a layer of silicon oxide or aluminum oxide disposed over the structures on the substrate. The layer is disposed over sidewalls and top surfaces of the structures, and a bottom surface of the trenches. The waveguide further includes a high index layer disposed over the layer. The high index layer is disposed over the sidewalls and the top surfaces of the structures, and the bottom surface of the trenches with the layer disposed in between the structures and the high index layer.

### CROSS-REFERENCE TO RELATED APPLICATIONS

This application claims priority to U.S. Provisional Patent Application Ser. No. 63/456,662, filed on Apr. 3, 2023, which is herein incorporated by reference.

### BACKGROUND

### Field

Embodiments of the present disclosure generally relate to waveguides. More specifically, embodiments described herein relate to improved waveguides with materials layers improving the optical properties of waveguides and methods of forming the same.

### Description of the Related Art

Virtual reality is generally considered to be a computer generated simulated environment in which a user has an apparent physical presence. A virtual reality experience can be generated in 3D and viewed with a head-mounted display (HMD), such as glasses or other wearable display devices that have near-eye display panels as lenses to display a virtual reality environment that replaces an actual environment.

Augmented reality (AR), however, enables an experience in which a user can still see through the display lenses of the glasses or other HMD device to view the surrounding environment, yet also see images of virtual objects that are generated to appear as part of the environment. Augmented reality can include any type of input, such as audio and haptic inputs, as well as virtual images, graphics, and video that enhance or augment the environment that the user experiences. Optical devices, such as augmented reality waveguide combiners, are used for overlaying images for users. Generated light is propagated through the waveguide until the light exits the waveguide and is overlaid on the ambient environment for the user. Reduced efficiency at specific wavelengths of light of the waveguide diminish the user's experience due to reduced intensity of images output by the waveguide.

Accordingly, what is needed in the art are optical devices and methods forming waveguides that increase color efficiency at specific wavelengths.

### SUMMARY

In one embodiment, a waveguide is provided. The waveguide including a substrate, a grating disposed in or on the substrate, the grating including a plurality of structures defined by a plurality of trenches, a layer of silicon oxide or aluminum oxide disposed over the structures on the substrate. The layer is disposed over sidewalls and top surfaces of the structures, and a bottom surface of the trenches. The waveguide further includes a high index layer disposed over the layer. The high index layer is disposed over the sidewalls and the top surfaces of the structures, and the bottom surface of the trenches with the layer disposed in between the structures and the high index layer.

In another embodiment, a method of forming a waveguide is provided. The method includes forming a grating in a substrate including a silicon-containing material, the gratings including a plurality of structures defined by a plurality of trenches, and forming a silicon oxide layer on the substrate, the silicon oxide layer is disposed over sidewalls and top surfaces of the structures, and a bottom surface of the trenches. The method further includes depositing a high index layer on the substrate. The high index layer is disposed over the sidewalls and the top surfaces of the structures, and the bottom surface of the trenches. The silicon oxide layer disposed in between the structures and the high index layer.

In another embodiment, a method of forming a waveguide is provided. The method includes forming a grating in a substrate, the gratings including a plurality of structures defined by a plurality of trenches, and forming an aluminum oxide layer on the substrate. The aluminum oxide layer is disposed over sidewalls and top surfaces of the structures, and a bottom surface of the trenches. The method further includes depositing a high index layer on the substrate. The high index layer is disposed over the sidewalls and the top surfaces of the structures, and the bottom surface of the trenches. The aluminum oxide layer disposed in between the structures and the high index layer

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a perspective, frontal view of a waveguide, according to embodiments.

FIG. 2 is a cross-sectional view of a waveguide with a silicon oxide layer, according to embodiments.

FIG. 3 is a cross-sectional view of a waveguide with a silicon oxide layer and an aluminum oxide layer, according to embodiments.

FIG. 4 is a cross-sectional view of a waveguide with an aluminum oxide layer, according to embodiments.

FIG. 5 is a schematic, cross-sectional view of an anneal processing chamber, according to embodiments.

FIG. 6 is a schematic, side view of an atomic layer deposition processing chamber, according to embodiments.

FIG. 7 is a flow diagram describing a method of forming waveguides, according to embodiments.

FIG. 8A-8D are cross-section views showing the operations of forming a waveguide, according to embodiments.

FIG. 9 is a flow diagram describing a method of forming waveguides, according to embodiments.

FIG. 10A-10C are cross-section views showing the operations of forming a waveguide, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to waveguides. More specifically, embodiments described herein relate to improved waveguides with materials layers improving the optical properties of one or more surface regions of waveguides and methods of forming the same.

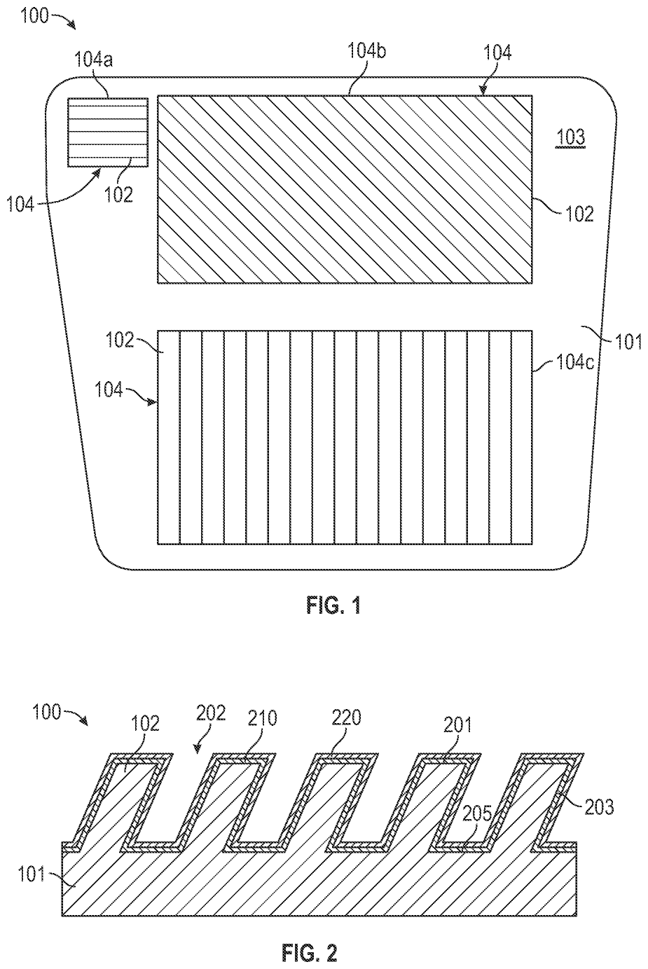

FIG. 1 is a perspective, frontal view of a waveguide 100. It is to be understood that the waveguide 100 described herein is an exemplary waveguide and that other waveguides may be used with or modified to accomplish aspects of the present disclosure. The waveguide 100 includes a plurality of structures 102. The structures 102 may be disposed over, under, or on a surface 103 of a substrate 101, or disposed in the substrate 101. The structures 102 are nanostructures have a sub-micron critical dimension, e.g., a width less than 1 micrometer. Regions of the structures 102 correspond to one or more gratings 104. In one embodiment, which can be combined with other embodiments described herein, the waveguide 100 includes at least a first grating 104a corresponding to an input coupling grating and a third grating 104c corresponding to an output coupling grating. In another embodiment, which can be combined with other embodiments described herein, the waveguide 100 further includes a second grating 104b. The second grating 104b corresponds to a pupil expansion grating or a fold grating.

The waveguide 100 may be selected to transmit a suitable amount of light of a desired wavelength or wavelength range, such as one or more wavelengths from about 100 to about 3000 nanometers. Without limitation, in some embodiments, the waveguide 100 is configured such that the waveguide 100 transmits greater than or equal to about 50% to about 100% of an IR to UV region of the light spectrum. The waveguide 100 may be formed from any suitable material, provided that the waveguide 100 can adequately transmit light in a desired wavelength or wavelength range. Waveguide selection may include optical devices of any suitable material, including, but not limited to, amorphous dielectrics, non-amorphous dielectrics, crystalline dielectrics, silicon oxide, silicon carbide, polymers, or combinations thereof. In some embodiments, which can be combined with other embodiments described herein, the waveguide 100 includes a transparent material. Suitable examples may include an oxide, sulfide, phosphide, telluride or combinations thereof. In one example, the waveguide 100 includes silicon (Si), silicon dioxide (SiO₂), germanium (Ge), silicon germanium (SiGe), sapphire, glass, silicon carbide, or high-index transparent materials such as high-refractive-index glass (refractive index greater than 2.0).

FIG. 2 is a cross-sectional view of one of the gratings 104 of the waveguide 100 with a silicon oxide layer 210, according to embodiments. The substrate 101 is a silicon-containing material. The structures 102 are spaced apart by trenches 202. The structures 102 include a top surface 201, and sidewalls 203. The trenches 202 have a bottom surface 205. As shown in FIG. 2, the structures 102 are formed in the substrate 101 of the waveguide 100. The silicon oxide layer 210 and a high index layer 220 (refractive index greater than 2.0) are disposed over the substrate 101. The structures 102 may be binary or angled as shown in FIG. 2. When the structures 102 are angled, the sidewalls 203 form an angle with the bottom surface 205.

The silicon oxide layer 210 is disposed over the structures 102 covering the sidewalls 203 and the top surfaces 201. The silicon oxide layer 210 covers the bottom surface 205 of the trenches 202. The silicon oxide layer 210 has a thickness of 15 nanometers (nm) or less over each of the sidewalls 203 and the top surfaces 201 of the structures 102 and the bottom surface 205 of the trenches 202. The silicon oxide layer 210 has a refractive index of about 1.5. The formation of the silicon oxide layer 210 is described herein in the method 700.

The high index layer 220 is disposed over the silicon oxide layer 210. The high index layer 220 covers the silicon oxide layer 210 across the structures 102. The high index layer 220 has a thickness of less than or equal to 15 nm over each of the sidewalls 203 and the top surfaces 201 of the structures 102 and the bottom surface 205 of the trenches 202 with the silicon oxide layer 210 disposed in between the structures 102 and the high index layer 220. The high index layer 220 includes titanium oxide or niobium oxide. The high index layer 220 has a refractive index greater than the refractive index of the silicon oxide layer 210. The deposition of the high index layer 220 is described herein in the method 700.

The silicon oxide layer 210 and the forming thereof substantially reduces the carbon content in the surface 103 of the substrate 101. By reducing the carbon by a substantial amount, the optical performance of the waveguide 100 is improved. These substantially lower levels of carbon improves the optical performance of the waveguide 100 and cause substantially lower levels of optical loss when compared to other waveguides. The efficiency of light at a green wavelength from the waveguide 100 in particular is increased due to the addition of the silicon oxide layer 210. The addition of the silicon oxide layer 210 changes the volume and refractive index of the structures 102. The change of the volume and refractive index of the structures 102 modulates a diffractive efficiency of the structures 102. The diffractive efficiency modulates the color efficiency to increase the efficiency of light at the green wavelength.

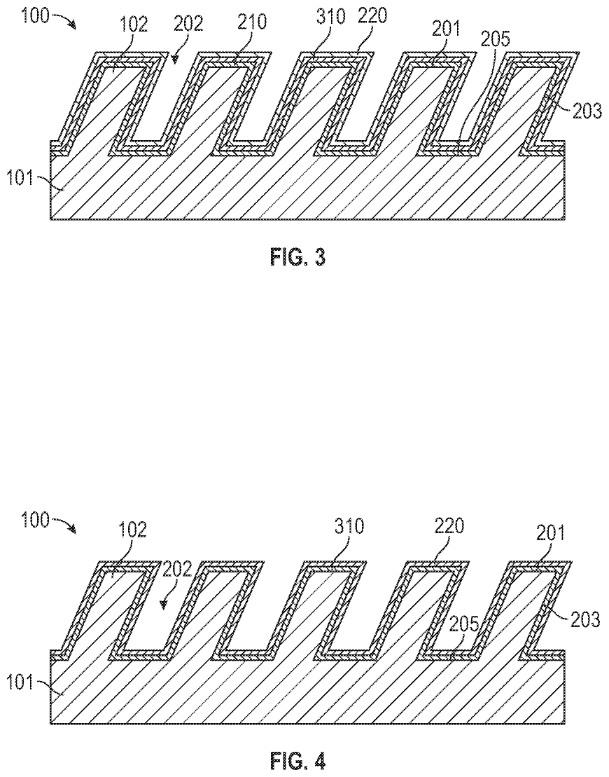

FIG. 3 is a cross-sectional view of the waveguide 100 with the silicon oxide layer 210 and an aluminum oxide layer 310, according to embodiments. The substrate 101 includes a silicon-containing material. The waveguide 100 includes the structures 102 described above. The waveguide 100 includes the silicon oxide layer 210 and the high index layer 220. The waveguide 100 further includes the aluminum oxide layer 310 disposed between the silicon oxide layer 210 and the high index layer 220.

The silicon oxide layer 210 is disposed over the structures 102 covering the sidewalls 203 and the top surfaces 201. The silicon oxide layer 210 covers the bottom surface 205 of the trenches 202. The silicon oxide layer 210 has a thickness of 15 nanometers (nm) or less over each of the sidewalls 203 and the top surfaces 201 of the structures 102 and the bottom surface 205 of the trenches 202. The silicon oxide layer 210 has a refractive index of about 1.5. The formation of the silicon oxide layer 210 is described herein in the method 700.

The aluminum oxide layer 310 is disposed over the silicon oxide layer 210. The aluminum oxide layer 310 covers the silicon oxide layer 210 across the structures 102. The aluminum oxide layer 310 has a thickness of 15 nanometers (nm) or less over each of the sidewalls 203 and the top surfaces 201 of the structures 102 and the bottom surface 205 of the trenches 202 with the silicon oxide layer 210 disposed in between the structures 102 and the aluminum oxide layer 310. The aluminum oxide layer 310 has a refractive index of about 1.7. The formation of the aluminum oxide layer 310 is described herein in the method 700.

The high index layer 220 is disposed over the aluminum oxide layer 310. The high index layer 220 covers the aluminum oxide layer 310 across the structures 102. The high index layer 220 has a thickness of less than or equal to 15 nm over each of the sidewalls 203 and the top surfaces 201 of the structures 102 and the bottom surface 205 of the trenches 202 with the silicon oxide layer 210 and aluminum oxide layer 310 disposed in between the structures 102 and the high index layer 220. The high index layer 220 includes titanium oxide or nioboium oxide. The high index layer 220 has a refractive index greater than the refractive index of the silicon oxide layer 210 and the aluminum oxide layer 310. The deposition of the high index layer 220 is described herein in the method 700.

The silicon oxide layer 210, the aluminum oxide layer 310, and the forming thereof substantially reduces the carbon content in the surface 103 of the substrate 101. By reducing the carbon by a substantial amount, the optical performance of the waveguide 100 is improved. These substantially lower levels of carbon improves the optical performance of the waveguide 100 and cause substantially lower levels of optical loss when compared to other waveguides. The efficiency of light at a green wavelength from the waveguide 100 in particular is increased due to the addition of the silicon oxide layer 210 and the aluminum oxide layer 310. The addition of the silicon oxide layer 210 and the aluminum oxide layer 310 changes the volume and refractive index of the structures 102. The change of the volume and refractive index of the structures 102 modulates a diffractive efficiency of the structures 102. The diffractive efficiency modulates the color efficiency to increase the efficiency of light at the green wavelength.

FIG. 4 is a cross-sectional view of the waveguide 100 with the aluminum oxide layer 310, according to embodiments. The substrate 101 may include the materials listed above. The waveguide 100 includes the structures 102 described above. The waveguide 100 includes the aluminum oxide layer 310 and the high index layer 220.

The aluminum oxide layer 310 is disposed over the structures 102 covering the sidewalls 203 and the top surfaces 201. The aluminum oxide layer 310 has a thickness of 15 nanometers (nm) or less over each of the sidewalls 203 and the top surfaces 201 of the structures 102 and the bottom surface 205 of the trenches 202. The aluminum oxide layer 310 has a refractive index of about 1.7. The formation of the aluminum oxide layer 310 is described herein in the method 900. The high index layer 220 is disposed on the aluminum oxide layer 310. The high index layer 220 has a refractive index greater than the refractive index of the aluminum oxide layer 310.

The high index layer 220 is disposed over the aluminum oxide layer 310. The high index layer 220 covers the aluminum oxide layer 310 across the structures 102. The high index layer 220 has a thickness of less than or equal to 15 nm over each of the sidewalls 203 and the top surfaces 201 of the structures 102 and the bottom surface 205 of the trenches 202 with the aluminum oxide layer 310 disposed in between the structures 102 and the high index layer 220. The high index layer 220 includes titanium oxide or niobium oxide. The high index layer 220 has a refractive index greater than the refractive index of the aluminum oxide layer 310. The high index layer 220 has a refractive index greater than the refractive index of the aluminum oxide layer 310. The deposition of the high index layer 220 is described herein in the method 900.

The aluminum oxide layer 310 and the forming thereof substantially reduces the carbon content in the surface 103 of the substrate 101. By reducing the carbon by a substantial amount, the optical performance of the waveguide 100 is improved. These substantially lower levels of carbon improves the optical performance of the waveguide 100 and cause substantially lower levels of optical loss when compared to other waveguides. The efficiency of light at a green wavelength from the waveguide 100 in particular is increased due to the addition of the aluminum oxide layer 310. The addition of the aluminum oxide layer 310 changes the volume and refractive index of the structures 102. The change of the volume and refractive index of the structures 102 modulates a diffractive efficiency of the structures 102. The diffractive efficiency modulates the color efficiency to increase the efficiency of light at the green wavelength.

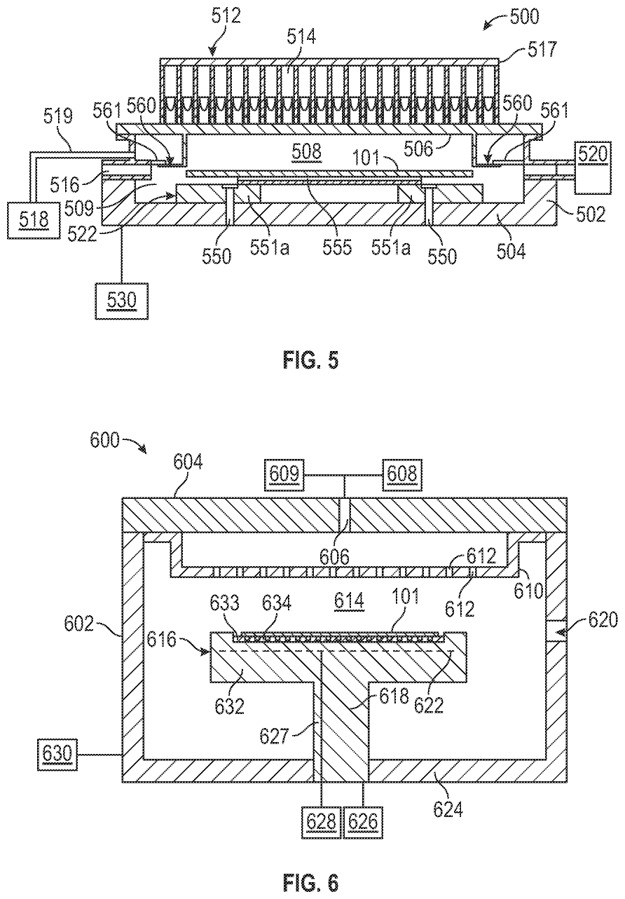

FIG. 5 is a schematic, cross-sectional views of an anneal processing chamber 500 according to embodiments of the disclosure. In some embodiments, the anneal processing chamber 500 is a Rapid Thermal Processing (RTP) chamber. In other embodiments, the anneal processing chamber 500 is any chamber applicable for use during a dry oxidation process. The anneal processing chamber 500 includes sidewalls 502, a chamber bottom 504 coupled to the sidewalls 502, and a window 506 disposed over the sidewalls 502. In some embodiments, the window 506 is made of quartz. The sidewalls 502 and the chamber bottom 504 form a chamber body. The sidewalls 502, the chamber bottom 504, and the window 506 define an upper volume 508 for processing a substrate 101 therein and a lower volume 509. The upper volume 508 is fluidly coupled to the lower volume 509, and is generally delineated from the lower volume 509 by a plane defined by a lower or bottom edge of a radiation shield 560.

A slit valve door 516 is formed through the sidewalls 502 for transferring a substrate 101 therethrough. The anneal processing chamber 500 is coupled to a gas source 518 by a conduit 519. The gas source 518 is configured to provide one or more processing gases to the upper volume 508 during processing. In some embodiments, the process gas may be hydrogen, steam, oxygen, nitrogen, or combinations thereof. A vacuum pump 520 is coupled to the anneal processing chamber 500 for pumping out the upper volume 508.

A substrate positioning assembly 522 is disposed in the lower volume 509 and configured to support, position, and/or rotate the substrate 101 during processing. The substrate positioning assembly 522 includes a substrate support 555, which may be a contact support such as a pedestal, or a non-contact substrate supporting device using flows of fluid to support, position, and/or rotate the substrate 101. The substrate positioning assembly 522 facilitates support of the substrate 101 on the substrate support 555. The substrate positioning assembly 522 includes a plurality of lift pins 550 (two are shown) disposed in lift pin supports 551a. The lift pins 550 lifts the substrate 101 off the substrate support 555 to facilitate ingress san egress of the substrate 101 through the slit valve door 516, as well as to facilitate transition of the substrate 101 from loading and processing positions.

A heating assembly 512 is disposed above the window 506 and configured to direct thermal energy towards the upper volume 508 through the window 506. The heating assembly 512 includes a plurality of lamps 514, such as high voltage tungsten halogen lamps disposed in a hexagonal pattern and controllable in zones to provide controlled heating to different zones of the upper volume 508. Each of the plurality of lamps 514 is inserted into a heating assembly base 517 for electrical connection to a power supply (not shown).

In some embodiments, a radiation shield 560 is coupled to the sidewalls 502 of the anneal processing chamber 500 and secured thereto via one or more optional mounts 561. The radiation shield 560 improves thermal processing due to improved temperature control and uniformity. The anneal processing chamber 500 described herein is provided as an example of a chamber to be used to process the waveguide 100. The waveguide 100 can be processed, in various embodiments, with other types of processing chambers.

A controller 530 includes a central processing unit (CPU), a memory containing instructions, and support circuits for the CPU. The controller 530 controls various items directly, or via other computers and/or controllers. In one or more embodiments, the controller 530 is communicatively coupled to dedicated controllers, and the controller 530 functions as a central controller.

The controller 530 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 530 are coupled to the CPU for supporting the CPU (a processor). The support circuits include cache, power supplies, clock circuits, input/output circuitry and subsystems, and the like. Operational parameters (such as a temperature of the substrate 101 and power applied to lamps 514) are stored in the memory as a software routine that is executed or invoked to turn the controller 530 into a specific purpose controller to control the operations of the various chambers/modules described herein. The controller 530 is configured to conduct any of the operations described herein. The instructions stored on the memory, when executed, cause one or more of operations of method 700 (described below) to be conducted.

FIG. 6 illustrates a schematic view of an atomic layer deposition (ALD) process chamber 600, according to embodiments. The ALD process chamber 600 includes a chamber body 602 and a lid 604 defining a process volume 614 therein. A bottom 624 of the chamber body 602 is opposite the lid 604. A port 606 is formed through the lid 604. A first gas source 608 is in fluid communication with the port 606. A second gas source 609 is also in fluid communication with the port 606. A showerhead 610 is coupled to the lid 604. A plurality of openings 612 are formed through the showerhead 610. The first gas source 608 and the second gas source 609 are in fluid communication with the process volume 614 via the port 606 and the openings 612.

A substrate support 616 is moveably disposed in the process volume 614 opposite the lid 604. The substrate support 616 includes a support body 632 disposed on a stem 618. The support body 632 includes a support surface 634 disposed opposite the stem 618 and facing the showerhead 610. In some embodiments, the support body 632 includes a heater or an electrostatic chuck. The support surface 634 includes a plurality of mesas 633. An opening 620 is formed through the chamber body 602 between the lid 604 and the bottom 624. During operation, a substrate 101 is loaded onto the support surface 634 through the opening 620. An actuator 626 is coupled to the substrate support 616 to move the substrate support 616 toward and away from the showerhead 610 for loading and processing the substrate 101 thereon.

An RF mesh 622 is disposed within the support body 632. One or more portions of the RF mesh 622 are disposed in a plane that is substantially perpendicular to the support surface 634. In some embodiments, a heating element is disposed within the support body 632. The heating element and RF mesh 622 may be used to heat the substrate 101 or electrostatically chuck the substrate 101. The heating element may be disposed below the RF mesh 622 and may be substantially perpendicular to the support surface 634. The RF mesh 622 is connected to one or more RF leads 627. The RF leads 627 are coupled to an RF power source 628. The RF power source 628 provides RF power to the RF mesh 622.

The ALD process chamber 600 is used for ALD processes. ALD processes include at least two deposition steps and at least two purging steps. A deposition step will be followed by a purging step to remove unused deposition gases in the ALD process chamber 600. During a first deposition step, a first gas is flowed through the first gas source 608 and a second gas is flowed through the second gas source 609. The first gas is a first precursor gas. In some embodiments, the first precursor gas is trimethylaluminium (TMA) gas. Different precursor gases may be used for different deposition steps. During the first deposition step, the second gas may be a purge gas. The purge gas may include argon gas. The purge gas may be used as a carrier gas to assist in flowing the one or more process gases over surfaces of the waveguide 100. During a first purge step, the purge gas is flowed from both gas sources to remove unused precursor gases. A second deposition step is performed after the first purge step. The second deposition step may include a second precursor gas flowed from the first gas source 608. In some embodiments, the second precursor gas is at least one of hydrogen, steam, oxygen, or nitrogen. The second gas is again flowed through the second gas source 609. After the second deposition step, a second purge step is performed. The ALD processing chamber 600 described herein is provided as an example of a chamber to be used to process the waveguide 100. The waveguide 100 can be implemented, in various embodiments, with other types of processing chambers.

A controller 630 such as the controller 530 described above is included in the Operational parameters (such as the flow of process gases, movement of the substrate support 616, and power applied to substrate support 616 to heat or chuck the substrate 101) are stored in the memory as a software routine that is executed or invoked to turn the controller 630 into a specific purpose controller to control the operations of the various chambers/modules described herein. The controller 630 is configured to conduct any of the operations described herein. The instructions stored on the memory, when executed, cause one or more of operations of method 700 and 900 (described below) to be conducted.

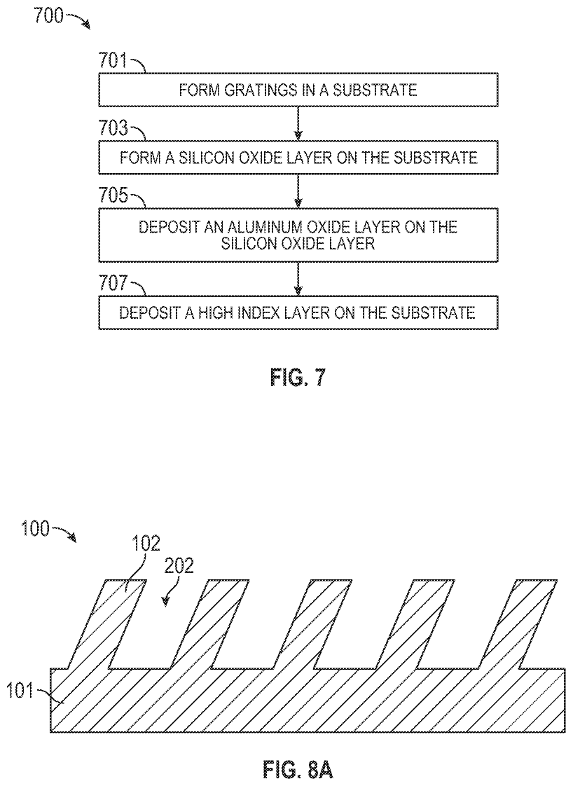

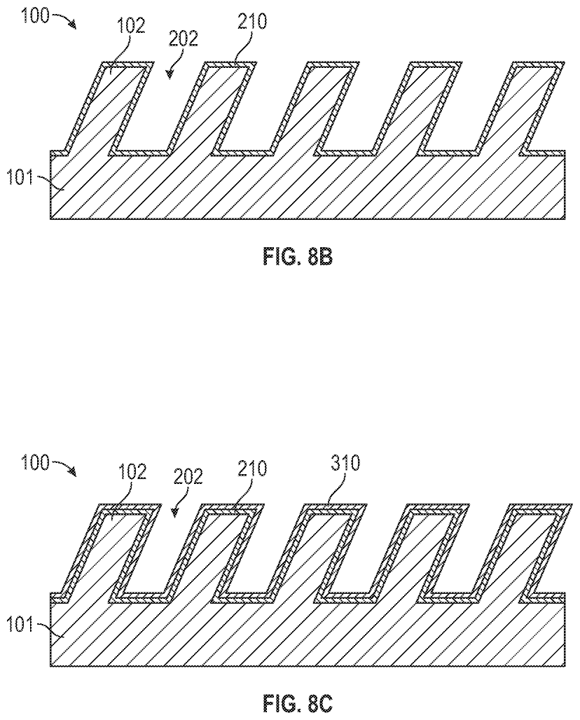

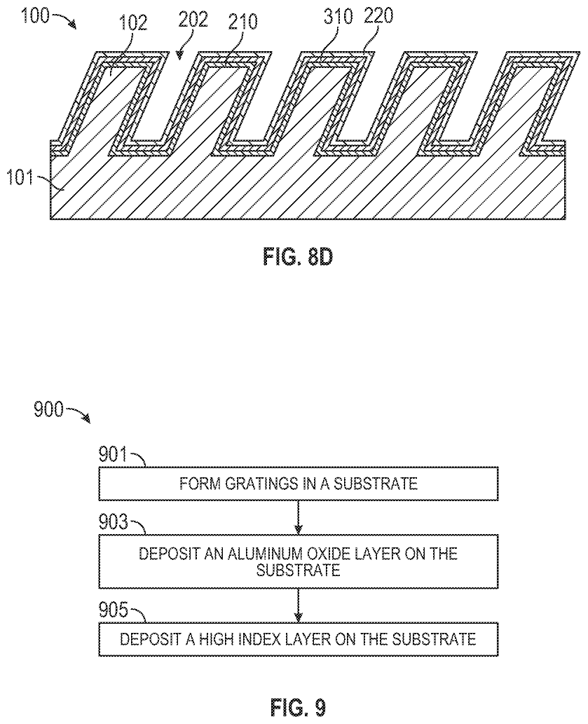

FIG. 7 is a flow diagram describing a method 700 of forming the waveguides 100, according to embodiments. FIG. 8A-8D are cross-section views showing the operations of forming the waveguide 100, according to embodiments. At operation 701, gratings 104 are formed in the substrate 101. The gratings are formed from structures 102. The structures 102 are formed by removing material in the substrate 101 forming the trenches 202 between the structures 102. The structures 102 are described above in FIG. 2. FIG. 8A illustrates the structures 102 formed in the substrate 101.

At operation 703, the silicon oxide layer 210 is formed on the structures 102. The silicon oxide layer 210 is formed during a dry oxidation process. Before the dry oxidation process, the substrate 101 is annealed. In some embodiments, the annealing process is performed in the anneal processing chamber 500. The annealing consists of the substrate 101 being exposed to a temperature set point. The plurality of lamps 514 are activated to heat the upper volume 508 to the temperature set point. Processing gases (e.g., hydrogen, steam, oxygen, and nitrogen) may be flowed over the substrate 101 via the gas source 518. Processing gases are exhausted through the vacuum pump 520. In some embodiments, an inert gas (e.g., argon) can be used as a carrier gas to assist in flowing the one or more process gases over surfaces of the substrate 101. In some embodiments, the temperature set point is a temperature from about 600° C. to about 2000° C., such as from about 900° C. to about 1400° C. The temperature during annealing can be maintained within a specified threshold (0.5 degrees ° C.) of the temperature set point. The duration of the annealing can be from about one minute to about three hours, such as from about five minutes to about one hour, such as about ten minutes. During the annealing, the pressure can be maintained at a pressure from about 250 Torr to about 1000 Torr, such as from about 300 Torr to about 760 Torr, such as about 400 Torr to about 500 Torr. In some embodiments, the annealing is performed in a different processing chamber.

After the annealing, the substrate 101 is subject to the dry oxidation process. In some embodiments, the dry oxidation process is performed in the anneal processing chamber 500. The dry oxidation process uses oxygen gas as the process gas. In some embodiments, the purge gas (e.g., argon) can be used as a carrier gas to assist in flowing the oxygen gas over surfaces of the substrate 101. The plurality of lamps 514 are activated to heat the upper volume 508 to a process temperature. The dry oxidation process is done at a temperature from about 600° C. to about 2000° C., such as from about 900° C. to about 1400° C., such as 1000° C. The oxygen gas is flowed from the gas source 518 to the upper volume 508 via the conduit 519. The oxygen flows over the substrate 101. The oxygen gas is heated in the upper volume 508. The heated oxygen gas interacts with the substrate 101 forming a silicon oxide layer 210. During the dry oxidation process, the pressure can be maintained at a pressure from about 250 Torr to about 1000 Torr, such as from about 300 Torr to about 850 Torr, such as about 760 Torr, which is atmospheric pressure. The dry oxidation process can be from about one minute to about three hours, such as from about five minutes to about one hour, such as about 8.5 minutes. The process conditions (pressure, flow rate of oxygen, timing) are selected to have the proper thickness of the silicon oxide layer 210. In some embodiments, the dry oxidation process is performed in a different processing chamber.

The annealing and dry oxidation processes create the silicon oxide layer 210 on the structures 102. FIG. 8B illustrates the silicon oxide layer 210 formed on the structures 102.

The annealing and dry oxidation processes create the silicon oxide layer 210 on the structures 102. In some embodiments, the annealing and dry oxidation processes can substantially reduce the carbon content in the surface 103 of the substrate 101 and the top surface 201 and sidewalls 203 of the structures 102 by at least 50%, such as by at least 80% (e.g., 5/6 of the carbon being removed), such as by at least 90%, such as by at least 99%. By reducing the carbon by a substantial amount, the optical performance of the waveguide 100 is improved. These substantially lower levels of carbon improves the optical performance of the waveguide 100 and cause substantially lower levels of optical loss when compared to the other waveguides. The efficiency of light at a green wavelength from the waveguide 100 in particular is increased due to the addition of the silicon oxide layer 210. The addition of the silicon oxide layer 210 changes the volume and refractive index of the structures 102. The change of the volume and refractive index of the structures 102 modulates a diffractive efficiency of the structures 102. The diffractive efficiency modulates the color efficiency to increase the efficiency of light at the green wavelength.

At optional operation 705, the aluminum oxide layer 310 is deposited on the silicon oxide layer 210. The aluminum oxide layer 310 is deposited using ALD. Prior to depositing the aluminum oxide layer 310, the substrate 101 is first annealed. In some embodiments, the annealing process is performed in the anneal processing chamber 500. The annealing consists of the substrate 101 being exposed to a temperature set point. The plurality of lamps 514 are activated to heat the upper volume 508 to the temperature set point. Processing gases (e.g., hydrogen, steam, oxygen, and nitrogen) may be flowed over the substrate 101 via the gas source 518. Processing gases are exhausted through the vacuum pump 520. In some embodiments, an inert gas (e.g., argon) can be used as a carrier gas to assist in flowing the one or more process gases over surfaces of the substrate 101. In some embodiments, the temperature set point is a temperature from about 600° C. to about 2000° C., such as from about 900° C. to about 1400° C. The temperature during annealing can be maintained within a specified threshold (0.5 degrees ° C.) of the temperature set point. The duration of the annealing can be from about one minute to about three hours, such as from about five minutes to about one hour, such as about ten minutes. During the annealing, the pressure can be maintained at a pressure from about 250 Torr to about 1000 Torr, such as from about 300 Torr to about 760 Torr, such as about 400 Torr to about 500 Torr. In some embodiments, the annealing is performed in a different processing chamber.

After the annealing, the substrate 101 is subject to an atomic layer deposition (ALD) process. In some embodiments, the annealing process is performed in the ALD processing chamber 600. The substrate 101 is positioned on the substrate support 616. The substrate 101 may be electrostatically chucked using the RF mesh 622. The substrate 101 may be heated using the heater disposed in the substrate support 616. The ALD process uses trimethylaluminium (TMA) gas as the first process gas and water (steam) as the second process gas. In some embodiments, the purge gas (e.g., argon) can be used as a carrier gas to assist in flowing the TMA gas and steam over surfaces of the substrate 101. The TMA gas is flowed into the process volume 614. The TMA gas reacts with the silicon oxide layer 210 on the substrate 101. The process volume 614 is purged with the purge gas. The steam is flowed into the process volume 614. The steam reacts with a layer formed on the silicon oxide layer 210 with the TMA gas. This reaction forms the aluminum oxide layer 310. The process volume 614 is purged with the purge gas again.

The ALD process is done at a temperature from about 200° C. to about 700° C., such as from about 250° C. to about 350° C., such as 300° C. During the ALD process, the pressure can be maintained at a pressure from about 250 Torr to about 1000 Torr, such as from about 300 Torr to about 850 Torr, such as about 760 Torr, which is atmospheric pressure. In some embodiments, the ALD process can be from about one minute to about three hours, such as from about five minutes to about one hour, such as about 8.5 minutes. The cycle time of the ALD process is 120 cycles. The pulse time of the TMA gas is 0.3 s. The pulse time of the steam is 0.2 s. The process time, cycles, pulse time of the TMA and the pulse time of the steam are selected to have the proper thickness of the aluminum oxide layer 310. In some embodiments, the ALD process is performed in a different processing chamber. FIG. 8C illustrates the aluminum oxide layer 310 deposited on the silicon oxide layer 210.

The annealing and ALD processes create the aluminum oxide layer 310 on the structures 102. The aluminum oxide layer and the forming thereof improves the optical performance of the waveguide 100. The waveguide 100 has substantially lower levels of optical loss when compared to other waveguides. The efficiency of light at a green wavelength from the waveguide 100 in particular is increased due to the addition of the aluminum oxide layer 310. The addition of the aluminum oxide layer 310 changes the volume and refractive index of the structures 102. The change of the volume and refractive index of the structures 102 modulates a diffractive efficiency of the structures 102. The diffractive efficiency modulates the color efficiency to increase the efficiency of light at the green wavelength.

At operation 707, the high index layer 220 is deposited on the substrate 101. In embodiments where the aluminum oxide layer 310 is included, the high index layer 220 is deposited on the aluminum oxide layer 310. In embodiments where the aluminum oxide layer is not included, the high index layer 220 is deposited on the silicon oxide layer 210. In some embodiments, the high index layer 220 may be deposited using an ALD process such as the ALD process used to deposit the aluminum oxide layer 310. FIG. 8D illustrates the high index layer 220 is deposited on the aluminum oxide layer 310.

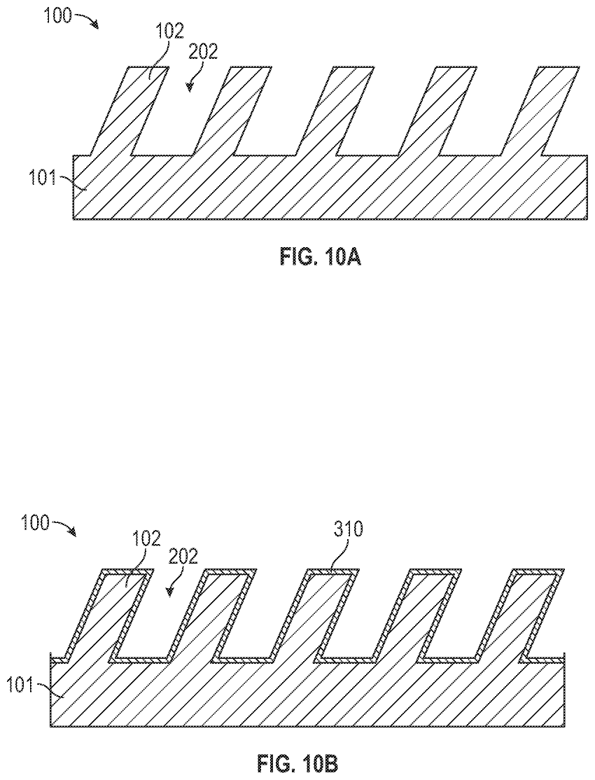

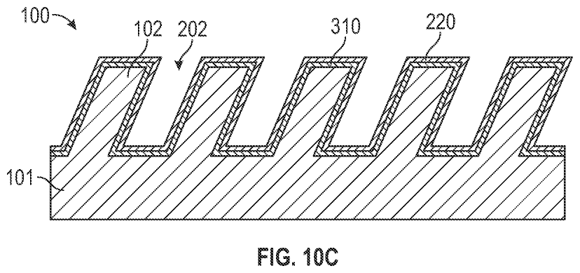

FIG. 9 is a flow diagram describing a method 900 of forming the waveguides 100, according to embodiments. FIG. 10A-10C are cross-section views showing the operations of forming the waveguide 100, according to embodiments. At operation 901, gratings 104 are formed in the substrate 101. The gratings are formed from structures 102. The structures 102 are formed by removing material in the substrate 101 forming the trenches 202 between the structures 102. The structures 102 are described above in FIG. 2. FIG. 10A illustrates the structures 102 formed in the substrate 101.

At operation 903, the aluminum oxide layer 310 is deposited on the structures 102. The aluminum oxide layer 310 is deposited using ALD. Prior to depositing the aluminum oxide layer 310, the substrate 101 is first annealed. In some embodiments, the annealing process is performed in the anneal processing chamber 500. The annealing consists of the substrate 101 being exposed to a temperature set point. The plurality of lamps 514 are activated to heat the upper volume 508 to the temperature set point. Processing gases (e.g., hydrogen, steam, oxygen, and nitrogen) may be flowed over the substrate 101 via the gas source 518. Processing gases are exhausted through the vacuum pump 520. In some embodiments, an inert gas (e.g., argon) can be used as a carrier gas to assist in flowing the one or more process gases over surfaces of the substrate 101. In some embodiments, the temperature set point is a temperature from about 600° C. to about 2000° C., such as from about 900° C. to about 1400° C. The temperature during annealing can be maintained within a specified threshold (0.5 degrees ºC) of the temperature set point. The duration of the annealing can be from about one minute to about three hours, such as from about five minutes to about one hour, such as about ten minutes. During the annealing, the pressure can be maintained at a pressure from about 250 Torr to about 1000 Torr, such as from about 300 Torr to about 760 Torr, such as about 400 Torr to about 500 Torr. In some embodiments, the annealing is performed in a different processing chamber.

After the annealing, the substrate 101 is subject to an atomic layer deposition (ALD) process. In some embodiments, the annealing process is performed in the ALD processing chamber 600. The substrate 101 is positioned on the substrate support 616. The substrate 101 may be electrostatically chucked using the RF mesh 622. The substrate 101 may be heated using the heater disposed in the substrate support 616. The ALD process uses trimethylaluminium (TMA) gas as the first process gas and water (steam) as the second process gas. In some embodiments, the purge gas (e.g., argon) can be used as a carrier gas to assist in flowing the TMA gas and steam over surface 103 of the substrate 101. The TMA gas is flowed into the process volume 614. The TMA gas reacts with the surface 103 of the substrate 101. The process volume 614 is purged with the purge gas. The steam is flowed into the process volume 614. The steam reacts with a layer formed on the surface 103 of the substrate 101 with the TMA gas. This reaction forms the aluminum oxide layer 310. The process volume 614 is purged with the purge gas again.

The ALD process is done at a temperature from about 200° C. to about 700° C., such as from about 250° C. to about 350° C., such as 300° C. During the ALD process, the pressure can be maintained at a pressure from about 250 Torr to about 1000 Torr, such as from about 300 Torr to about 850 Torr, such as about 760 Torr, which is atmospheric pressure. In some embodiments, the ALD process can be from about one minute to about three hours, such as from about five minutes to about one hour, such as about 8.5 minutes. The cycle time of the ALD process is 120 cycles. The pulse time of the TMA gas is 0.3 s. The pulse time of the steam is 0.2 s. The process time, cycles, pulse time of the TMA and the pulse time of the steam are selected to have the proper thickness of the aluminum oxide layer 310. In some embodiments, the ALD process is performed in a different processing chamber. FIG. 10B illustrates the aluminum oxide layer 310 deposited on the silicon oxide layer 210.

The annealing and ALD processes create the aluminum oxide layer 310 on the structures 102. In some embodiments, the annealing and ALD processes can substantially reduce the carbon content in the surface 103 of the substrate 101 and the top surface 201 and sidewalls 203 of the structures 102 by at least 50%, such as by at least 80% (e.g., 5/6 of the carbon being removed), such as by at least 90%, such as by at least 99%. By reducing the carbon by a substantial amount, the optical performance of the waveguide 100 is improved. These substantially lower levels of carbon improves the optical performance of the waveguide 100 and cause substantially lower levels of optical loss when compared to other waveguides The efficiency of light at a green wavelength from the waveguide 100 in particular is increased due to the addition of the aluminum oxide layer 310. The addition of the aluminum oxide layer 310 changes the volume and refractive index of the structures 102. The change of the volume and refractive index of the structures 102 modulates a diffractive efficiency of the structures 102. The diffractive efficiency modulates the color efficiency to increase the efficiency of light at the green wavelength.

At operation 905, the high index layer 220 is deposited on the on the aluminum oxide layer 310. In some embodiments, the high index layer 220 may be deposited using an ALD process such as the ALD process used to deposit the aluminum oxide layer 310. FIG. 10C illustrates the high index layer 220 is deposited on the aluminum oxide layer 310.

In summation, embodiments of the present disclosure generally relate to waveguides. More specifically, embodiments described herein relate to improved waveguides with materials layers improving the optical properties of one or more surface regions of waveguides and methods of forming the same. The disclosure allows for the efficiency of light at a green wavelength from the waveguide 100 to be increased. The addition of the silicon oxide layer 210 or the aluminum oxide layer 310 reduce the optical loss at the green wavelength through material properties. Also, the addition of the silicon oxide layer 210 and/or the aluminum oxide layer 310 change the volume and refractive index of the structures 102. The change of the volume and refractive index of the structures 102 modulates a diffractive efficiency of the structures 102. The diffractive efficiency modulates the color efficiency to increase the efficiency of light at the green wavelength.

While the foregoing is directed to embodiments of the present disclosure, other and further embodiments of the disclosure may be devised without departing from the basic scope thereof, and the scope thereof is determined by the claims that follow.

What is claimed is:

1. A waveguide, comprising:
a substrate;
a grating disposed in or on the substrate, the grating comprising a plurality of structures defined by a plurality of trenches;
a layer of silicon oxide or aluminum oxide disposed over the structures on the substrate, the layer disposed over sidewalls and top surfaces of the structures, and a bottom surface of the trenches; and
a high index layer disposed over the layer, the high index layer disposed over the sidewalls and the top surfaces of the structures, and the bottom surface of the trenches with the layer disposed in between the structures and the high index layer.

2. The waveguide of claim 1, wherein the layer is a silicon oxide layer and the high index layer is disposed on the silicon oxide layer.

3. The waveguide of claim 2, wherein an aluminum oxide layer is disposed between the silicon oxide layer and the high index layer.

4. The waveguide of claim 2, wherein the silicon oxide layer has a thickness of less than or equal to 15 nm.

5. The waveguide of claim 1, wherein the substrate comprises a silicon-containing material.

6. The waveguide of claim 1, wherein the layer is an aluminum oxide layer and the high index layer is disposed on the aluminum oxide layer.

7. The waveguide of claim 6, wherein the aluminum oxide layer has a thickness of less than or equal to 15 nm.

8. The waveguide of claim 6, wherein the high index layer includes titanium oxide or niobium oxide.

9. The waveguide of claim 1, wherein the substrate comprises silicon, silicon dioxide, germanium, silicon germanium, sapphire, glass, or silicon carbide.

10. A method of forming a waveguide, comprising:
forming a grating in a substrate comprising a silicon-containing material, the gratings comprising a plurality of structures defined by a plurality of trenches;
forming a silicon oxide layer on the substrate, the silicon oxide layer disposed over sidewalls and top surfaces of the structures, and a bottom surface of the trenches; and
depositing a high index layer on the substrate, the high index layer disposed over the sidewalls and the top surfaces of the structures, and the bottom surface of the trenches with the silicon oxide layer disposed in between the structures and the high index layer.

11. The method of claim 10, wherein the silicon oxide layer is formed with a dry oxidation process, the dry oxidation process using oxygen as a process gas.

12. The method of claim 11, wherein the dry oxidation process is performed at a temperature of about 900° C. to about 1400° C.

13. The method of claim 10, further comprising depositing an aluminum oxide layer prior to the high index layer, the aluminum oxide layer disposed between the silicon oxide layer and the high index layer.

14. The method of claim 13, wherein the aluminum oxide layer is deposited using an atomic layer deposition process.

15. The method of claim 14, wherein the atomic layer deposition process uses trimethylaluminium gas and steam as process gases.

16. A method of forming a waveguide, comprising:
forming a grating in a substrate, the gratings comprising a plurality of structures defined by a plurality of trenches;
forming an aluminum oxide layer on the substrate, the aluminum oxide layer disposed over sidewalls and top surfaces of the structures, and a bottom surface of the trenches; and
depositing a high index layer on the substrate, the high index layer over the sidewalls and the top surfaces of the structures, and the bottom surface of the trenches with the aluminum oxide layer disposed in between the structures and the high index layer.

17. The method of claim 16, wherein the aluminum oxide layer is deposited using an atomic layer deposition process.

18. The method of claim 17, wherein the atomic layer deposition process uses trimethylaluminium gas and steam as process gases.

19. The method of claim 17, wherein the atomic layer deposition process is performed at a temperature of about 250° C. to about 350° C.

20. The method of claim 17, wherein a cycle time of the atomic layer deposition process is 120 cycles.
